(19) United States
(12) Patent Application Publication
(10) Pub. No.: US 2016/0114563 A1
(43) Pub. Date: Apr. 28, 2016

(54) Improved mobile electronic parts

(71) Applicant: SOLVAY SPECIALTY POLYMERS USA, LLC, Alpharetta, GA (US)

(72) Inventors: Geoffrey Scott Underwood, Atlanta, GA (US); Gregory C. Plithides, Los Gatos, CA (US); Mohammad Jamal El-Hibri, Atlanta, GA (US); Hong Chen, Alpharetta, GA (US); Sebastien Petillon, Atlanta, GA (US); Philippe Brasseur, Genval (BE); Suresh R. Sriram, Aurora, IL (US)

(21) Appl. No.: 14/897,923

(22) PCT Filed: Jun. 10, 2014
(86) PCT No.: PCT/EP2014/061963

§ 371 Date: Dec. 11, 2015

Related U.S. Application Data
(60) Provisional application No. 61/833,736, filed on Jun. 11, 2013.

(30) Foreign Application Priority Data
Dec. 12, 2013 (EP) 13196777.0

(51) Int. Cl. B32B 15/08; H05K 3/00; B32B 15/20

(52) U.S. Cl. CPC B32B 15/08; B32B 15/20; H05K 3/00; B32B 2255/06; B32B 2255/26; B32B 2457/00; B32B 2307/546; B32B 2307/714; B32B 2307/558

(57) ABSTRACT

A mobile electronic part comprising: (i) a shaped metal part, at least part of the surface thereof being coated with at least one polymer layer (L), wherein the metal is selected from a group consisting of magnesium, aluminum and alloys of these metals, and wherein said polymer layer (L) comprises at least one polymer selected from an aromatic polyamide-imide polymer [(PAI) polymer, herein after] or a poly(ethersulfone) polymer [(PESU) polymer herein after], and (ii) a thermoplastic resin composition layer [layer (T), herein after] fixed to the at least one polymer layer (L) of said shaped metal part wherein said composition comprises at least one thermoplastic polymer [polymer (T), herein after].

### CROSS-REFERENCE TO RELATED APPLICATIONS

This application claims priority to U.S. Provisional application No. 61/833,736 filed on Jun. 11, 2013 and to European application No. 13196777 filed Dec. 12, 2013, the whole content of each of these applications being incorporated herein by reference for all purposes.

### TECHNICAL FIELD

The present invention relates to mobile electronic parts comprising a thermoplastic resin composition layer being fixed to a polymeric material layer, being coated onto a shaped metal part, said mobile electronic parts having improved mechanical properties, in particular high stiffness and strength, and excellent chemical resistance. The invention further relates to mobile electronic devices comprising said mobile electronic parts, to methods of manufacturing said mobile electronic parts and said mobile electronic devices.

### BACKGROUND ART

Nowadays, many mobile electronics devices such as mobile phones, tablets, laptop computers, MP3 players, and the like, have a significant portion of the device made out of low density metal such as magnesium, aluminum and alloys thereof. Since, the use of metals for mobile electronics parts comes with certain drawbacks, for example, magnesium is somewhat expensive and their use sometimes limits design flexibility, most of the mobile electronics devices also comprise polymeric parts.

As the mobile electronic devices and the parts therein are getting thinner and smaller for even more portability and convenience, methods which make it possible to directly bond metals and polymeric components together are important when considering volume reduction of the device. In these methods, there is thus a high need to ensure good adhesion between the metal part, in particular aluminum part and polymeric components.

Additionally, anodization is an important process that is typically carried out on metal parts, e.g. aluminum parts and/or aluminum/plastic composite parts. Anodization is an electro chemical process where the aim is to build an oxide layer on the aluminum surface. It is mostly used as an increased corrosion protection surface treatment on aluminum details. Other reasons for anodizing are notably maintaining the “new-look”, obtaining a dirt-repelling surface, obtaining a decorative colored surface, obtaining a touch appealing surface, obtaining a surface resistant to wear and obtaining an electrical insulating surface. In this regards, anodization being performed on parts already comprising polymeric layers, creates a need for polymeric materials with excellent chemical resistance to various aggressive acids. However, polymeric materials possessing excellent chemical resistance, such as notably commercially available poly(etheretherketone) (PEEK) resins or polyetherimide (PEI) resins are not always sticking very well to metal surfaces, and to overcome this problem nowadays the metal part has to have a geometry that allows a mechanical interlock between the metal part and the polymeric part.

As mentioned above, as parts get smaller there is thus a high demand to avoid mechanical interlocking.

Accordingly, some solutions have already been developed in the art, one of these is for example the Nano Molding Technology. The Nano Molding Technology (NMT-method), as notably described in detail in a Master Thesis, entitled “‘Nano Molding Technology on Cosmetic Aluminum Parts in Mobile Phones—an experimental study’, by Carl-Ola Annefors and Sara Petersson for Division of Production and Materials Engineering—LTH—2007, at Lund University, the whole content of which is herein incorporated by reference, and in European Patent Applications EP1459882 and EP1559542, the whole content of those are herein incorporated by reference, is a method which makes it possible to directly bond metals, in particular aluminum, and plastics together. This method is carried out by treating the metal surface, including etching with various chemicals, and then injection molding the desired plastic components on the treated surface. The advantage of this method is the possibility to manufacture light and strong products.

However, one of the major drawbacks of this method is the fact that not all thermoplastic polymers, as most commonly use plastics within mobile electronic devices, are compatible with the NMT-method. For example, in EP1459882 and EP1559542, two resins, in particular a polybutylene terephthalate resin (PBT) or polyphenylene sulfide resin (PPS) are described as being compatible with the NMT-method. It is also known that the method also works for aromatic polyamide resins such as for the commercially available Kalix® (modified polyarylamide polymer) polymer from Solvay Specialty Polymers U.S.A, L.L.C.

Especially, PPS is known as one of the best polymer for both the NMT-method and resisting the anodization process.

Despite the fact that the mobile electronic devices and the parts therein are getting thinner and smaller, they still need to possess a certain structural strength and stiffness so that they will not be damaged in normal handling and occasional drops. It should be mentioned that one of the drawbacks is that PPS is rather brittle.

In view of all the above, there is thus a continuous need for lighter and smaller mobile electronic devices and structural parts therein which have at the same time excellent chemical resistance, improved ductility (i.e. good elongation properties), impact resistance, high stiffness (and in particular high flexural modulus), as well as strength, thus having the necessary structural integrity and breakage resistance required under for example the harsh drop testing conditions.

### SUMMARY OF INVENTION

The present invention addresses the above detailed needs and relates to a mobile electronic part comprising:
(i) a shaped metal part, at least part of the surface being coated with at least one polymer layer (L), wherein the metal is selected from a group consisting of magnesium, aluminum and alloys of these metals, and wherein said polymer layer (L) comprises at least one polymer selected from an aromatic polyamide-imide polymer [(PAI) polymer, herein after] or a poly(ethersulfone) polymer [(PESU) polymer herein after], and
(ii) a thermoplastic resin composition layer [layer (T), herein after] fixed to the at least one polymer layer (L) of said shaped metal part wherein said composition comprises at least one thermoplastic polymer [polymer (T), herein after].

The invention also pertains to a mobile electronic part comprising a shaped metal part, at least part of the surface being coated with at least one polymer layer (L), wherein the metal is selected from a group consisting of magnesium, aluminum and alloys of these metals, and wherein said polymer layer (L) comprises at least one poly(ethersulfone) polymer [(PESU) polymer herein after].

The invention further pertains to a method for making the above mentioned mobile electronic part.

The invention also pertains to a mobile electronic device comprising the above mentioned mobile electronic part.

### DETAILED DESCRIPTION OF THE PRESENT INVENTION

### The Shaped Metal Part

As said, the metal of the shaped metal part is selected from a group consisting of magnesium, aluminum and alloys of these metals. A preferred metal is aluminum alloy.

In a preferred embodiment of the present invention, the shaped metal part is a shaped aluminum alloy part. An aluminum alloy is known for its low density, high strength, good workability and tooling and together with its high resistance to corrosion. Aluminum alloys have notably a tensile strength of 70 to 700 MPa.

In the present invention, various aluminum alloys can be used such as notably those standardized as “1000 series” to “7000 series” by JIS (Japanese Industrial Standards) and those of die-casting grade.

An example of a suitable aluminum alloy is for example Al 5052 H32 is a wrought alloy with Mg as the main alloying element, 2.2-2.8%. Other alloying elements are: Cr 0.15-0.35%; Cu 0.1%; Fe 0.4%; Mn 0.1%; Si 0.25% and Zn 0.1%.

The Composition of Layer (T) [Composition (T), Herein after]

The composition (T) comprises advantageously the at least one polymer (T) in an amount of more than 50% wt., preferably in an amount of more than 70% wt., preferably more than 80% wt., more preferably more than 90% wt., still more preferably more than 95% wt., even more preferably more than 99% wt., based on the total weight of the composition (T).

If desired, the composition (T) consists of the at least one polymer (T).

The at least one polymer (T) of the composition (T) may be chosen from any kind of thermoplastic polymers. Of course, more than one polymer (T) may be present in the composition (T).

For the purpose of the present invention, the term “thermoplastic polymer” is understood to mean a polymer existing, at room temperature, below its glass transition temperature, if it is amorphous, or below its melting point if it is semi-crystalline, and which is linear (i.e. not reticulated). This polymer has the property of becoming soft when it is heated and of becoming rigid again when it is cooled, without there being an appreciable chemical change. Such a definition may be found, for example, in the encyclopedia called “Polymer Science Dictionary”, Mark S. M. Alger, London School of Polymer Technology, Polytechnic of North London, UK, published by Elsevier Applied Science, 1989.

More specifically, such polymer (T) may be selected from the group consisting of polyamides, polyesters, poly(aryletherketone)s, in particular poly(etheretherketone)s; poly(etherketoneketone); poly(etherketone)s; poly(etheretherketoneketone)s or a poly(etherketoneetherketoneketone)s, poly(arylethersulfone)s, in particular poly(ethersulfone)s, polyimides, polyetherimides, polyamideimide, liquid crystalline polymers, polycarbonates, polyolefins, poly(phenylene sulfide), polyphenylene oxide, polyacrylates, acrylonitrile butadiene styrene polymer, polyoxymethylene, polystyrene, polyphenylene sulfide, polyvinylidene fluoride, polytetrafluoroethylene, polyvinylidene chloride, polyvinyl chloride, thermoplastic elastomers and mixtures thereof.

The at least one polymer (T) of the composition (T) is more preferably selected from the group consisting of at least one poly(arylethersulfone) polymer [(PAES) polymer], at least one poly(aryletherketone) polymer [(PAEK) polymer], and mixtures thereof.

### The Poly(Aryletherketone) Polymer

Within the context of the present invention the mention “at least one poly(aryletherketone) polymer [(PAEK) polymer]” is intended to denote one or more than one (PAEK) polymer. Mixtures of (PAEK) polymer can be advantageously used for the purposes of the invention.

In the rest of the text, the expressions “(PAEK) polymer” are understood, for the purposes of the present invention, both in the plural and the singular, that is to say that the inventive composition may comprise one or more than one (PAEK) polymer.

For the purpose of the invention, the term “poly(aryletherketone) polymer [(PAEK) polymer]” is intended to denote any polymer, comprising recurring units, more than 50% moles of said recurring units are recurring units (R_{PAEK}) comprising a Ar—C(O)—Ar′ group, with Ar and Ar′, equal to or different from each other, being aromatic groups. The recurring units (R_{PAEK}) are generally selected from the group consisting of formulae (J-A) to (J-O), herein below:

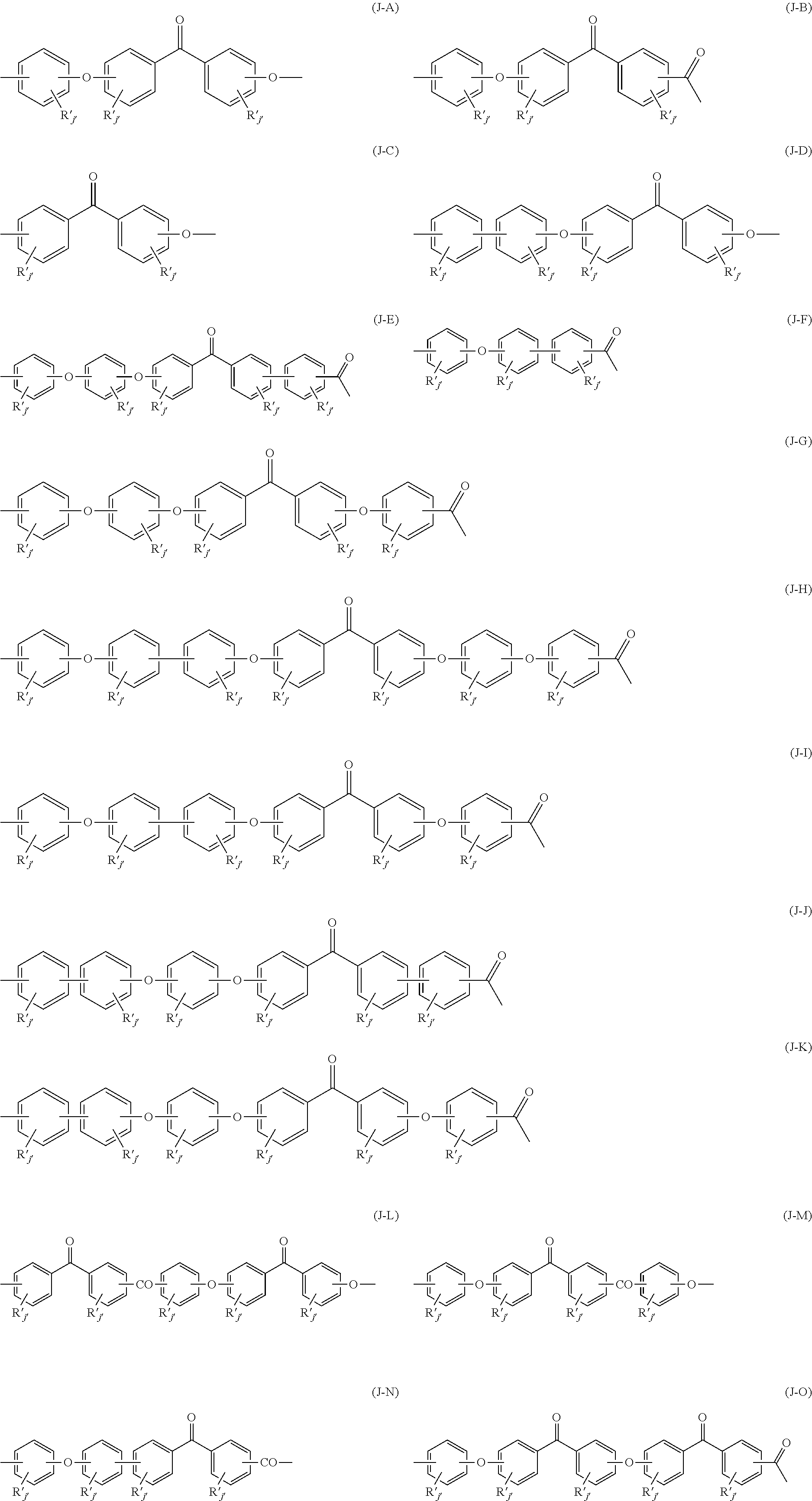

wherein:
each of R′, equal to or different from each other, is selected from the group consisting of halogen, alkyl, alkenyl, alkynyl, aryl, ether, thioether, carboxylic acid, ester, amide, imide, alkali or alkaline earth metal sulfonate, alkyl sulfonate, alkali or alkaline earth metal phosphonate, alkyl phosphonate, amine and quaternary ammonium;
j′ is zero or is an integer from 0 to 4.

In recurring unit (R_{PAEK}), the respective phenylene moieties may independently have 1,2-, 1,4- or 1,3-linkages to the other moieties different from R′ in the recurring unit. Preferably, said phenylene moieties have 1,3- or 1,4-linkages, more preferably they have 1,4-linkage.

Still, in recurring units (R_{PAEK}), j′ is at each occurrence zero, that is to say that the phenylene moieties have no other substituents than those enabling linkage in the main chain of the polymer.

Preferred recurring units (R_{PAEK}) are thus selected from those of formulae (J′-A) to (J′-O) herein below:

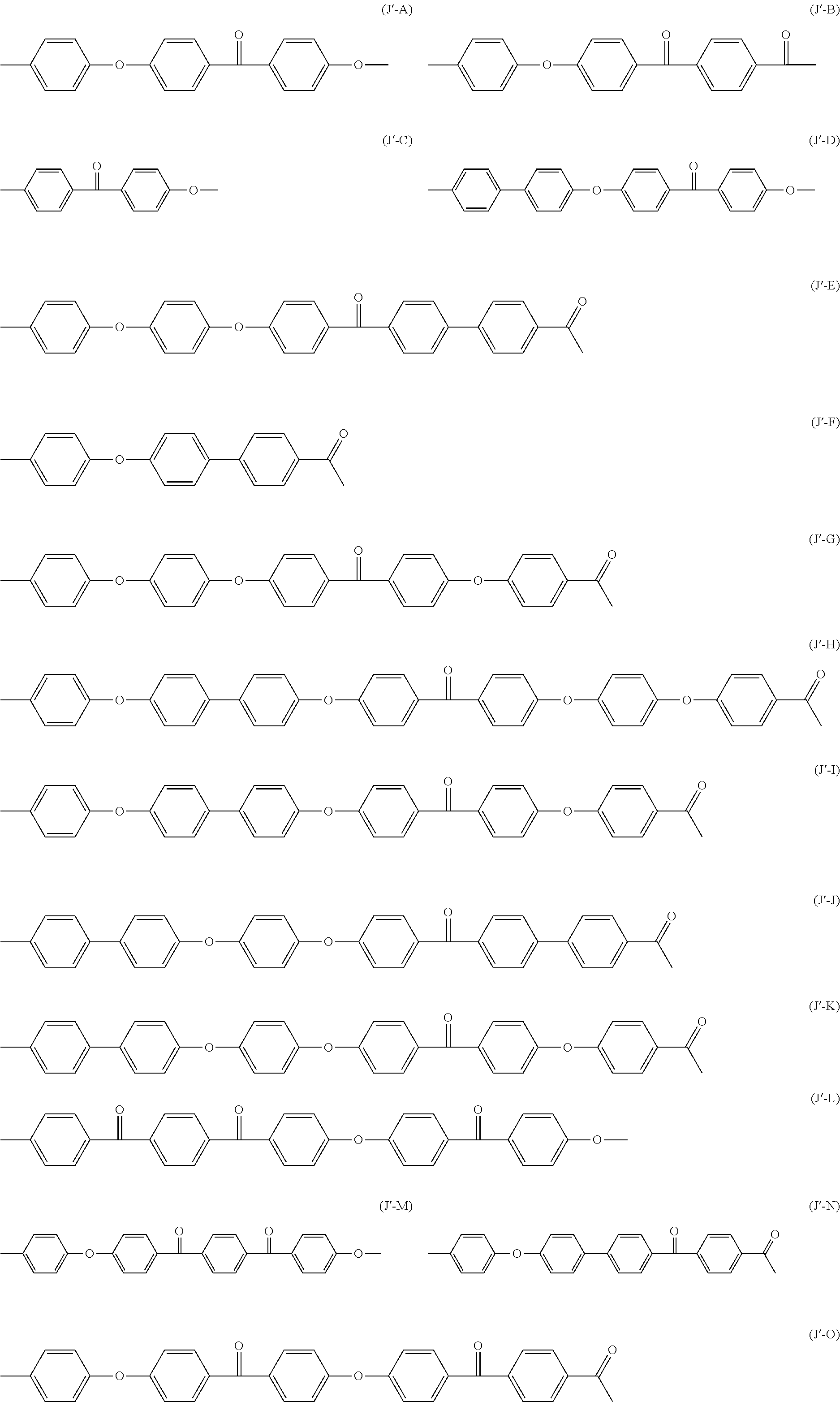

In the (PAEK) polymer, as detailed above, preferably more than 60%, more preferably more than 80%, still more preferably more than 90% moles of the recurring units are recurring units (R_{PAEK}), as above detailed.

Still, it is generally preferred that substantially all recurring units of the (PAEK) polymer are recurring units (R_{PAEK}), as detailed above; chain defects, or very minor amounts of other units might be present, being understood that these latter do not substantially modify the properties of (R_{PAEK}).

The (PAEK) polymer may be notably a homopolymer, a random, alternate or block copolymer. When the (PAEK) polymer is a copolymer, it may notably contain (i) recurring units (R_{PAEK}) of at least two different formulae chosen from formulae (J-A) to (J-O), or (ii) recurring units (R_{PAEK}) of one or more formulae (J-A) to (J-O) and recurring units (R*_{PAEK}) different from recurring units (R_{PAEK}).

As will be detailed later on, the (PAEK) polymer may be a poly(etheretherketone) polymer [(PEEK) polymers, herein after]. Alternatively, the (PAEK) polymer may be a poly(etherketoneketone) polymer [(PEKK) polymer, herein after], a poly(etherketone) polymer [(PEK) polymer, hereinafter], a poly(etheretherketoneketone) polymer [(PEEKK) polymer, herein after], or a poly(etherketoneetherketoneketone) polymer [(PEKEKK) polymer, herein after].

The (PAEK) polymer may also be a blend composed of at least two different (PAEK) polymers chosen from the group consisting of (PEKK) polymers, (PEEK) polymers, (PEK) polymers and (PEKEKK) polymers, as above detailed.

For the purpose of the present invention, the term “(PEEK) polymer” is intended to denote any polymer of which more than 50% by moles of the recurring units are recurring units (R_{PAEK}) of formula J′-A.

Preferably more than 75% by moles, preferably more than 85% by moles, preferably more than 95% by moles, preferably more than 99% by moles of the recurring units of the (PEEK) polymer are recurring units of formula J′-A. Most preferably all the recurring units of the (PEEK) polymer are recurring units of formula J′-A.

For the purpose of the present invention, the term “(PEKK) polymer” is intended to denote any polymer of which more than 50% by moles of the recurring units are recurring units (R_{PAEK}) of formula J′-B.

Preferably more than 75% by moles, preferably more than 85% by moles, preferably more than 95% by moles, preferably more than 99% by moles of the recurring units of the (PEKK) polymer are recurring units of formula J′-B. Most preferably all the recurring units of the (PEKK) polymer are recurring units of formula J′-B.

For the purpose of the present invention, the term “(PEK) polymer” is intended to denote any polymer of which more than 50% by moles of the recurring units are recurring units (R_{PAEK}) of formula J′-C.

Preferably more than 75% by moles, preferably more than 85% by moles, preferably more than 95% by moles, preferably more than 99% by moles of the recurring units of the (PEK) polymer are recurring units of formula J′-C. Most preferably all the recurring units of the (PEK) polymer are recurring units of formula J′-C.

For the purpose of the present invention, the term “(PEEKK) polymer” is intended to denote any polymer of which more than 50% by moles of the recurring units are recurring units (R_{PAEK}) of formula J′-M.

Preferably more than 75% by moles, preferably more than 85% by moles, preferably more than 95% by moles, preferably more than 99% by moles of the recurring units of the (PEEKK) polymer are recurring units of formula J′-M. Most preferably all the recurring units of the (PEEKK) polymer are recurring units of formula J′-M.

For the purpose of the present invention, the term “(PEKEKK) polymer” is intended to denote any polymer of which more than 50% by moles of the recurring units are recurring units (R_{PAEK}) of formula J′-L.

Preferably more than 75% by moles, preferably more than 85% by moles, preferably more than 95% by moles, preferably more than 99% by moles of the recurring units of the (PEKEKK) polymer are recurring units of formula J′-L. Most preferably all the recurring units of the (PEKEKK) polymer are recurring units of formula J′-L.

Excellent results were obtained when the (PAEK) polymer was a (PEEK) homopolymer, i.e. a polymer of which substantially all the recurring units of the (PEEK) polymer are recurring units of formula J′-A, wherein chain defects, or very minor amounts of other units might be present, being understood that these latter do not substantially modify the properties of the (PEEK) homopolymer.

Non limitative examples of commercially available polyaryletherketone (PAEK) resins suitable for the invention include the KETASPIRE® polyetheretherketone commercially available from Solvay Specialty Polymers USA, LLC.

The (PAEK) polymer can be prepared by any method known in the art for the manufacture of poly(aryl ether ketone)s.

### The Poly(Arylethersulfone) Polymer

Within the context of the present invention the mention “at least one poly(arylethersulfone) polymer [(PAES) polymer]” is intended to denote one or more than one (PAES) polymer. Mixtures of (PAES) polymer can be advantageously used for the purposes of the invention.

In the rest of the text, the expressions “(PAES) polymer” are understood, for the purposes of the present invention, both in the plural and the singular, that is to say that the inventive composition may comprise one or more than one (PAES) polymer.

For the purpose of the invention, the term “poly(arylethersulfone) polymer [(PAES) polymer]” is intended to denote any polymer, at least 50% moles of the recurring units (R_{PAES}) thereof comprise at least one group of formula (S):

—Ar—SO₂—Ar′— formula (S)

with Ar and Ar′, equal to or different from each other, being aromatic groups.

Recurring units (R_{PAES}) generally comply with formula, shown below:

Ar¹-(T′-Ar²)ₙ—O—Ar³—SO₂—[Ar⁴-(T-Ar²)ₙ—SO₂]ₘ—Ar⁵—O—

wherein:
Ar¹, Ar², Ar³, Ar⁴, and Ar⁵, equal to or different from each other and at each occurrence, are independently a aromatic mono- or polynuclear group;
T and T′, equal to or different from each other and at each occurrence, is independently a bond or a divalent group optionally comprising one or more than one heteroatom; preferably T and T′ are independently selected from the group consisting of a bond, —CH₂—, —C(O)—, —C(CH₃)₂—, —C(CF₃)₂—, —C(═CCl₂)—, —SO₂—, and —C(CH₃)(CH₂CH₂COOH)—,
n and m, equal to or different from each other, are independently zero or an integer of 1 to 5.

Recurring units (R_{PAES}) can be notably selected from the group consisting of those of formulae (S-A) to (S-D) herein below:

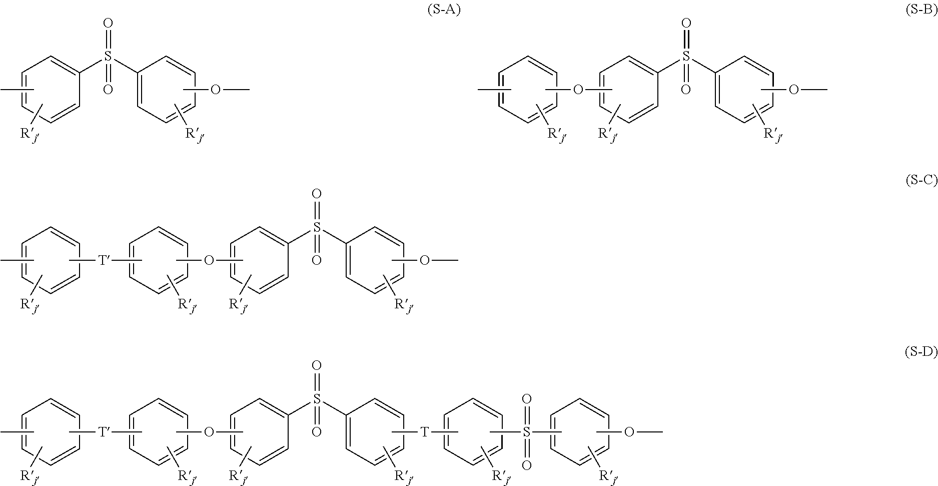

wherein:
each of R′, equal to or different from each other, is selected from the group consisting of halogen, alkyl, alkenyl, alkynyl, aryl, ether, thioether, carboxylic acid, ester, amide, imide, alkali or alkaline earth metal sulfonate, alkyl sulfonate, alkali or alkaline earth metal phosphonate, alkyl phosphonate, amine and quaternary ammonium;
j′ is zero or is an integer from 0 to 4;
T and T′, equal to or different from each other are defined as above.

In a preferred embodiment of the invention, at least 50% moles of the recurring units of the (PAES) polymer are recurring units (R_{SP-2}) and/or recurring units (R_{SP-3}):

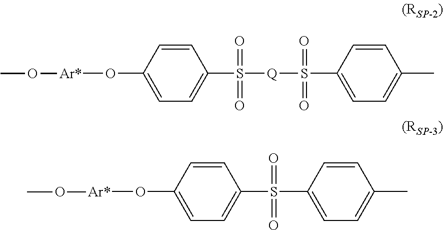

wherein:
Q and Ar*, equal or different from each other and at each occurrence, are independently a divalent aromatic group; preferably Ar* and Q equal or different from each other and at each occurrence, are independently selected from the group consisting of the following structures:

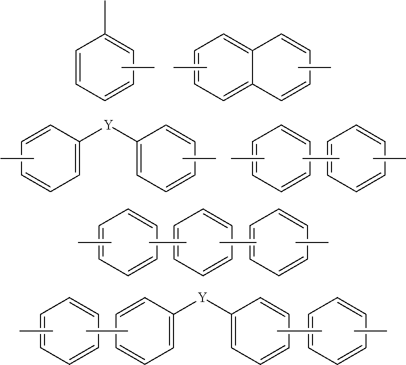

and corresponding optionally substituted structures, with Y being —O—, —CH═CH—, —C≡C—, —S—, —C(O)—, —(CH₂)ₙ—, —C(CF₃)₂—, —C(CH₃)₂—, —SO₂—, —(CF₂)ₙ—, with n being an integer from 1 to 5 and mixtures thereof; and mixtures thereof.

Recurring units (R_{SP-2}) are preferably selected from the group consisting of:

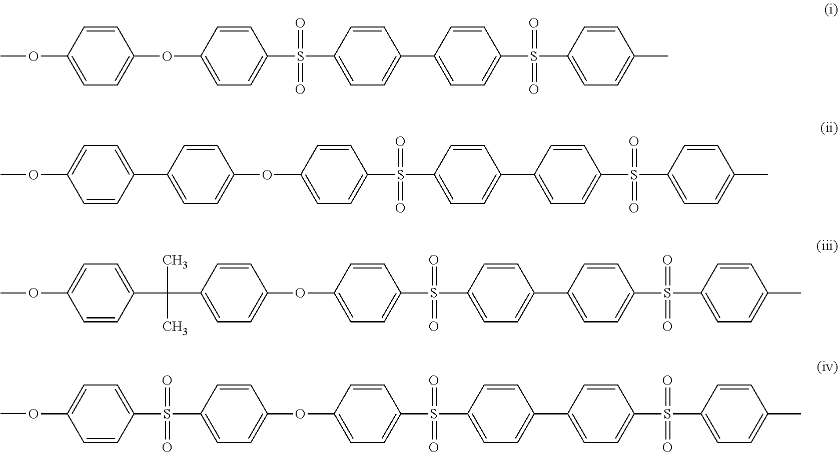

and mixtures thereof.

Recurring units (R_{SP-3}) are preferably selected from the group consisting of:

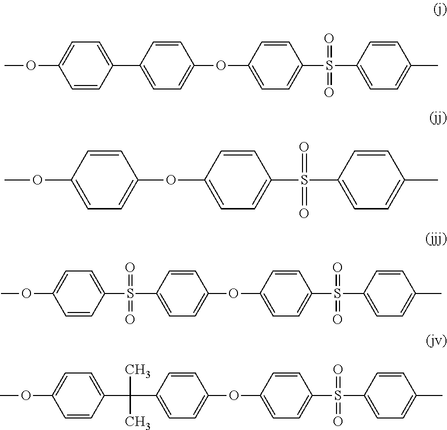

and mixtures thereof.

According to a preferred embodiment of the invention, the (PAES) polymer of the composition (T) comprises at least 50% moles, preferably 70% moles, more preferably 75% moles of recurring units (R_{SP-2}) and/or (R_{SP-3}), still more preferably, it contains no recurring unit other than recurring units (R_{SP-2}) and/or (R_{SP-3}).

As will be detailed later on, the (PAES) polymer may be a poly(phenylene sulfone) polymer [(PPSU) polymer]. Alternatively, the (PAES) polymer may be a poly(ethersulfone) polymer [(PESU) polymer, herein after] or a poly(sulfone) polymer [(PSU) polymer, hereinafter].

The (PAES) polymer may also be a blend composed of at least two different (PAES) polymers chosen from the group consisting of (PPSU) polymers, (PESU) polymers and (PSU) polymers, as above detailed.

For the purpose of the present invention, the term “(PEKEKK) polymer” is intended to denote any polymer of which more than 50% by moles of the recurring units are recurring units (R_{PAEK}) of formula J′-L.

For the purpose of the invention, the term “poly(phenylene sulfone) polymer [(PPSU) polymer]” is intended to denote any polymer of which more than 50% by moles of the recurring units are recurring units of formula (j), as shown above

In a preferred embodiment of the present invention, more than 75% by moles, preferably more than 90% by moles, more preferably more than 99% by moles, even more preferably substantially all the recurring units of the (PPSU) polymer are recurring units (j), chain defects or minor amounts of other recurring units might be present, being understood that these latter do not substantially modify the properties of the (PPSU) polymer.

Non limitative examples of commercially available (PPSU) polymer include the RADEL® PPSU and DURADEX® D-3000 PPSU commercially available from Solvay Specialty Polymers USA, L.L.C.

For the purpose of the invention, the term “poly(ethersulfone) polymer [(PESU) polymer]” is intended to denote any polymer of which more than 50% by moles of the recurring units are recurring units of formula (jjj), as shown above.

In a preferred embodiment of the present invention, more than 75% by moles, preferably more than 90% by moles, more preferably more than 99% by moles, even more preferably substantially all the recurring units of the (PESU) polymer are recurring units (jjj), chain defects or minor amounts of other recurring units might be present, being understood that these latter do not substantially modify the properties of the (PESU) polymer.

Non limitative examples of commercially available (PESU) polymers include notably VERADEL® PESU, commercially available from Solvay Specialty Polymers USA, L.L.C.

For the purpose of the invention, the term “poly(sulfone) polymer [(PSU) polymer]” is intended to denote any polymer of which more than 50% by moles of the recurring units are recurring units of formula (jv), as shown above

In a preferred embodiment of the present invention, more than 75% by moles, preferably more than 90% by moles, more preferably more than 99% by moles, even more preferably substantially all the recurring units of the (PSU) polymer are recurring units (jv), chain defects or minor amounts of other recurring units might be present, being understood that these latter do not substantially modify the properties of the (PESU) polymer.

Non limitative examples of commercially available (PSU) polymers include notably UDEL® PSU commercially available from Solvay Specialty Polymers USA, L.L.C.

Excellent results were obtained when the (PAES) polymer of the composition (T) was selected from the group consisting of (PPSU) polymer, (PESU) polymer, (PSU) polymer or mixture thereof.

It is further understood that depending on the final end use of the mobile electronic part, in some cases the (PPSU) polymer may be preferred, in other cases the (PSU) polymer might be more preferred and in still other cases, the (PESU) polymer might be more preferred.

In one embodiment of the present invention, the composition (T) is comprising, preferably consisting of:
at least one poly(aryl ether ketone) polymer [(PAEK) polymer], as defined above
at least one polymer (T), as defined above, different from the (PAEK) polymer, and
optionally at least one reinforcing filler.

Non limitative examples of blends including at least one (PAEK) polymer are notably described in EP 1 999 212 B1, U.S. Pat. No. 4,804,724, U.S. Pat. No. 4,684,699, WO 2008/116939 and references therein, the whole content of all those are herein incorporated by reference.

Resins commercialized by Solvay Specialty Polymers USA, L.L.C. as AvaSpire® polyaryletherketone (PAEK) resins comply with this criterion.

According to all embodiments and preferred embodiments, the composition (T) of the present invention may optionally comprise a reinforcing filler.

A large selection of reinforcing fillers may be added to the composition (T).

It is understood that the skilled person will easily recognize the reinforcing filler which fits best its composition and encompassed end uses. Generally, the reinforcing filler is chosen depending on its chemical nature, its length, diameter, ability to feed nicely in compounding equipment without bridging and surface treatment (notably because good interfacial adhesion between the reinforcing filler and the polymer improves the strength and the toughness of the blend).

They are preferably selected from fibrous and particulate fillers.

A fibrous reinforcing filler is considered herein to be a material having length, width and thickness, wherein the average length is significantly larger than both the width and thickness. Generally, such a material has an aspect ratio, defined as the average ratio between the length and the largest of the width and thickness of at least 5. Preferably, the aspect ratio of the reinforcing fibers is at least 10, more preferably at least 20, still more preferably at least 50.

In one embodiment, the reinforcing fibrous filler may be selected from glass fibers; carbon fibers such as notably graphitic carbon fibers (some of them having possibly a graphite content of above 99%), amorphous carbon fibers, pitch-based carbon fibers (some of them having possibly a graphite content of above 99%), PAN-based carbon fibers; synthetic polymeric fiber; aramid fiber; aluminum fiber; aluminum silicate fibers; oxide of metals of such aluminum fibers; titanium fiber; magnesium fiber; boron carbide fibers; rock wool fiber; steel fiber; asbestos; wollastonite; silicon carbide fibers; boron fibers, graphene, carbon nanotubes (CNT) and the like.

In another embodiment, the fillers are non-fibrous and may be selected from talc, mica, titanium dioxide, kaolin, calcium carbonate, calcium silicate, magnesium carbonate.

When the reinforcing filler is present in the composition (T), the at least one reinforcing filler is present in an amount of advantageously at least 5 wt. %, preferably at least 10 wt. %, more preferably at least 15 wt. %, based on the total weight of the composition (T).

The reinforcing filler is also present in an amount of advantageously at most 50 wt. %, preferably at most 45 wt. %, more preferably at most 40 wt. %, still more preferably at most 30 wt. %, based on the total weight of the composition (T).

### Other Ingredients

The composition (T) may further optionally comprise other ingredients such as a colorant such as notably a dye and/or a pigment, ultraviolet light stabilizers, heat stabilizers, antioxidants, an acid scavenger, processing aids, nucleating agents, an internal lubricant and/or an external lubricant, flame retardants, a smoke-suppressing agent, an anti-static agent, an anti-blocking agent, and/or conductivity additive such as carbon black and carbon nanofibrils.

When one or more other ingredients are present, their total weight, based on the total weight of composition (T), is usually below 50%, preferably below 20%, more preferably below 10% and even more preferably below 5%.

Composition (T) is comprised in the mobile electronic part in an amount of advantageously at least 1 wt. %, preferably at least 5 wt. % and still more preferably at least 10 wt. %, based on the total weight of the mobile electronic part.

Besides, composition (T) is comprised in the mobile electronic part in an amount of advantageously at most 99 wt. %, preferably at most 95 wt. % and still more preferably at most 80 wt. %, the total weight of the mobile electronic part.

### The Polymer Layer (L)

For the purpose of the present invention, the expression “at least one polymer layer (L)” is understood both in the plural and in the singular, that is to say that the mobile electronic part may comprise one or more than one polymer layer (L).

The thickness of the polymer layer (L) is advantageously of at most 100 μm, preferably of at most 75 μm, more preferably of at most 50 μm and even more preferably of at most 25 μm.

In a preferred embodiment, the thickness of the polymer layer (L) ranges from 0.5 to 100 μm, more preferably from 2 to 50 μm.

The (PAI) polymer or the (PESU) polymer are comprised in the polymer layer (L) in an amount of advantageously at least 50 wt. %, preferably at least 75 wt. % and still more preferably at least 80 wt. %, based on the total weight of the polymer layer (L).

Besides, The (PAI) polymer or the (PESU) polymer are comprised in the polymer layer (L) in an amount of advantageously at most 99.9 wt. %, preferably at most 95 wt. % and still more preferably at most 90 wt. %, the total weight of the polymer layer (L).

The polymer layer (L) of the invention is preferably consisting essentially of (PAI) polymer or the (PESU) polymer.

For the purpose of the present invention, the expression “consisting essentially of” are intended to denote that any additional ingredient different from the (PAI) polymer or the (PESU) polymer is present in an amount of at most 1% by weight, based on the total weight of the polymer layer (L).

It is known in the art that the (PAI) polymer and the (PESU) polymer are particularly well suited for providing a polymer layer (L), more specifically a coating layer, having high adhesion to substrates, such as notably metal substrates, in particular aluminum alloy substrates and they provide good chemical and thermal resistance.

### (PAI) Polymer

For the purpose of the present invention, “aromatic polyamide-imide polymer [(PAI) polymer]” is intended to denote any polymer comprising more than 50% moles of recurring units comprising at least one aromatic ring, at least one imide group, as such and/or in its amic acid form, and at least one amide group which is not included in the amic acid form of an imide group [recurring units (R_{PAI})].

The recurring units (R_{PAI}) are advantageously chosen among those of formula:

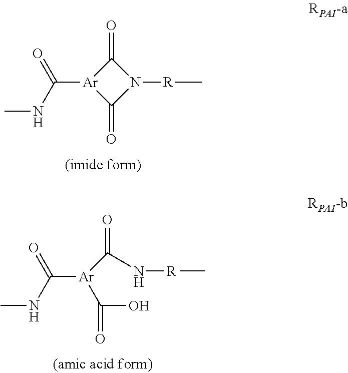

wherein:

Ar is a trivalent aromatic group; typically Ar is selected from the group consisting of following structures:

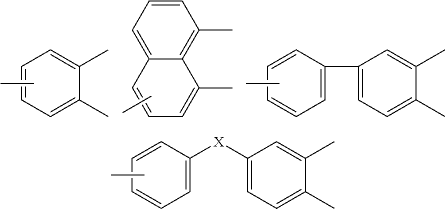

and corresponding optionally substituted structures, with X being —O—, —C(O)—, —CH₂—, —C(CH₃)₂—, —C(CF₃)₂—, —(CF₂)_{q}—, with q being an integer from 1 to 5;

R is a divalent aromatic group; typically R is selected from the group consisting of following structures:

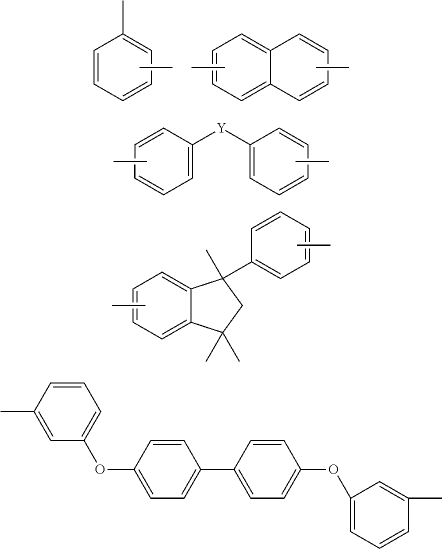

and corresponding optionally substituted structures, with Y being —O—, —S—, —SO₂—, —CH₂—, —C(O)—, —C(CH₃)₂—, —C(CF₃)₂—, —(CF₂)_{q}, q being an integer from 1 to 5.

Preferably, the aromatic polyamide-imide comprises more than 50% of recurring units (R_{PAI}) comprising an imide group in which the imide group is present as such, like in recurring units (R_{PAI}-a), and/or in its amic acid form, like in recurring units (R_{PAI}-b).

Recurring units (R_{PAI}) are preferably chosen from recurring units (l), (m) and (n), in their amide-imide (a) or amide-amic acid (b) forms:

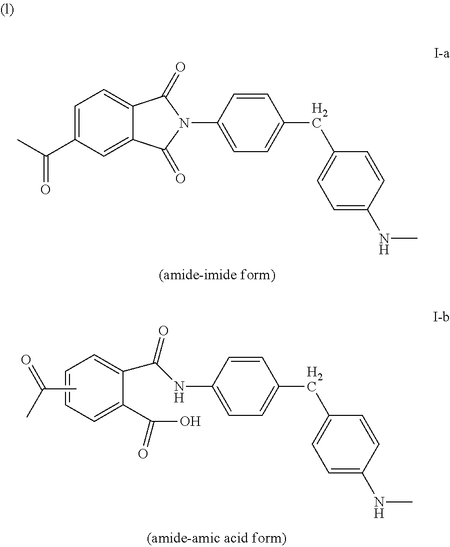

wherein the attachment of the two amide groups to the aromatic ring as shown in (l-b) will be understood to represent the 1,3 and the 1,4 polyamide-amic acid configurations;

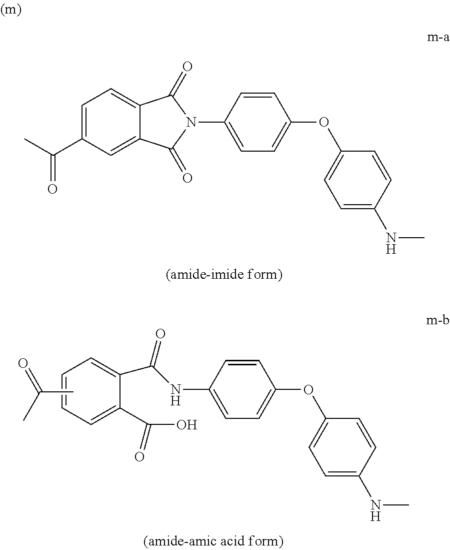

wherein the attachment of the two amide groups to the aromatic ring as shown in (m-b) will be understood to represent the 1,3 and the 1,4 polyamide-amic acid configurations; and

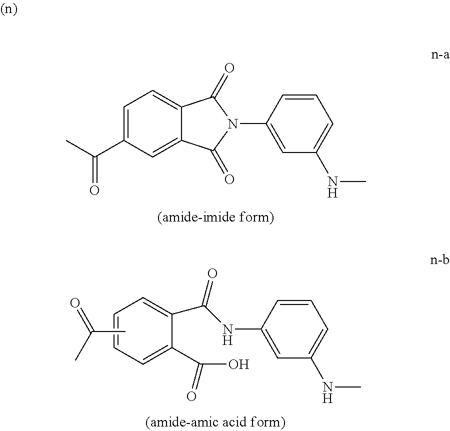

wherein the attachment of the two amide groups to the aromatic ring as shown in (n-b) will be understood to represent the 1,3 and the 1,4 polyamide-amic acid configurations.

More preferably, the (PAI) polymer comprises more than 90% moles of recurring units (R_{PAI}). Still more preferably, it contains no recurring unit other than recurring units (R_{PAI}). Polymers commercialized by Solvay Specialty Polymers USA, L.L.C. as TORLON® polyamide-imides comply with this criterion.

The (PAI) polymer can be manufactured according to known methods in the art.

Processes for preparing (PAI) polymers are disclosed in detail, for example, in British Patent No. 1,056,564, U.S. Pat. No. 3,661,832 and U.S. Pat. No. 3,669,937.

For example, the (PAI) polymer can be notably manufactured by a process including the polycondensation reaction between at least one acid monomer chosen from trimellitic anhydride and trimellitic anhydride monoacid halides and at least one comonomer chosen from diamines and diisocyanates.

Among the trimellitic anhydride monoacid halides, trimellitic anhydride monoacid chloride is preferred.

The comonomer comprises preferably at least one aromatic ring. Besides, it comprises preferably at most two aromatic rings. More preferably, the comonomer is a diamine. Still more preferably, the diamine is chosen from the group consisting of 4,4′-diaminodiphenylmethane, 4,4′-diaminodiphenylether, m-phenylenediamine and mixtures thereof.

In the present invention, the (PAI) polymer is most conveniently provided as a coating composition comprising a liquid medium, as discussed in more detail below.

### (PESU) Polymer

The (PESU) polymer, as described above, may be notably a homopolymer, or a copolymer such as a random or a block copolymer. When the (PESU) polymer is a copolymer, its recurring units are advantageously a mix of recurring units (jjj) and of recurring units (R_{PESU}*). These recurring units (R_{PESU}*) can notably be selected from the group consisting of those of formulae (j), (jj) and (jv), as shown above.

The (PESU) polymer can also be a blend of the previously cited homopolymer and copolymer.

The (PESU) polymers can be prepared by known methods.

The (PESU) polymer has advantageously a melt flow rate (MFR) equal to or higher than 4 g/10 min at 380° C. and under a load of 2.16 kg, preferably equal to or higher than 7 g/10 min at 380° C. and under a load of 2.16 kg, more preferably equal to or higher than 10 g/10 min at 380° C. and under a load of 2.16 kg, as measured in accordance with ASTM method D1238; to measure said melt flow rate, a Tinius Olsen Extrusion Plastometer melt flow test apparatus can be used.

Upper boundary for the melt flow rate of the (PESU) polymer is not critical and will be selected by the skilled in the art as a matter of routine work. It is nevertheless understood that when the (PESU) polymer possibly comprised in the composition (T) possesses advantageously a melt flow rate of at most 100 g/10 min, preferably at most 80 g/10 min, more preferably at most 70 g/10 min, still more preferably at most 60 g/10 min, most preferably at most 50 g/10 min, when measured in accordance with ASTM method D1238 at 380° C. and under a load of 2.16 kg.

According to certain embodiments, the (PESU) polymer can have a melt flow rate of 50 g/10 min or less, preferably of 40 g/10 min or less at 380° C. and under a load of 2.16 kg, preferably of 25 g/10 min or less at 380° C. and under a load of 2.16 kg: in other words, the (PESU) polymer of this embodiment will have a melt flow rate, measured as above detailed, ranging from at least 4 g/10 min to 50 g/10 min or less, preferably ranging from at least 15 g/10 min to 40 g/10 min or less, at 380° C. and under a load of 2.16 kg. VERADEL® A-201 NT PESU and VERADEL® A-301 NT PESU are examples of (PESU) polymers suitable for being used in this embodiment.

The VERADEL® PESU weight average molecular weight can be 20,000 to 100,000 grams per mole (g/mol) as determined by gel permeation chromatography using ASTM D5296 with polystyrene standards. In some embodiments the VERADEL® PESU weight average molecular weight can be 40,000 to 80,000 grams per mole (g/mol).

According to certain embodiments, the (PESU) polymer can be functionalized by one or more functional groups.

For the purpose of the present invention, the functional group may have bonding to atoms of the polymer chain, as a side chain group [side group] or be present as polymer chain end groups [end group]. Preferably, the functional group is a functional end group.

The functional group in the (PESU) polymer is preferably selected from a group consisting of hydroxyl, in particular phenol OH, carboxyl (—COOA where A is hydrogen or an alkali metal, anhydride and epoxide groups.

The functional group in the (PESU) polymer is most preferably a phenol OH group.

In a preferred embodiment of the present invention, the (PESU) polymer has advantageously a number of phenol OH groups being equal to or more than 10 μeq/g, preferably equal to or more than 20 μeq/g, more preferably equal to or more than 30 μeq/g, even more preferably equal to or less more than 50 μeq/g.

Upper boundary for the number of phenol OH group of the (PESU) polymer is not critical and will be selected by the skilled in the art as a matter of routine work. It is nevertheless understood that the (PESU) polymer has advantageously a number of phenol OH groups being equal to or less than 400 μeq/g, preferably equal to or less than 300 μeq/g, more preferably equal to or less than 200 μeq/g, even more preferably equal to or less than 100 μeq/g.

Analytical methods can be used for the determination of the total number of functional groups in the (PESU) polymer, including notably titration methods, spectroscopic measurements such as IR and NMR or radioactive measurements such as for polymers with labeled end-groups.

Preferably, the total number of phenol OH groups in the (PESU) polymer of the present invention are suitably determined by a titration method, preferably a potentiometric titration method.

For the determination of the total number of phenol OH groups, a base is suitably used as titrant. Suitable bases are in general those having a K_{b} value equal to of at least 1000 times greater than the K_{b} value of the de-protonated carboxyl end group. A suitable bases is notably tetrabutylammonium hydroxide in a mixture of toluene and methanol.

The base is in general dissolved in an organic solvent. The organic solvent to be used may, for example, be toluene, dimethyl formamide, dimethyl acetamide, dimethylsulfoxide, sulfolane, tetrahydrofuran, acetonitrile, dioxane, methanol, ethanol and mixture thereof.

The methods for achieving functionalized (PESU) polymers are well known in the art and include notably conducting the reaction with excess of the Bisphenol S monomer.

For example, a polymer commercialized by Solvay Specialty Polymers USA, L.L.C. as Viradel® 3600RP functionalized polyethersulfones (r-PESU) comply with this criterion.

Other examples of functionalized polyethersulfones (r-PESU) polymers commercialized by Solvay Specialty Polymers USA, L.L.C. comply with this criterion are notably Virantage® 10200, Virantage® 10300, and Virantage® 10700 functionalized polyethersulfones (r-PESU).

In the present invention, the (PESU) polymer is most conveniently provided as a coating composition comprising a liquid medium, as discussed in more detail below.

### The Mobile Electronic Part

For the purpose of the present invention, the term “mobile electronic part” is intended to denote any part present in a mobile electronic device.

The term “mobile electronic device” is intended to denote an electronic device that is designed to be conveniently transported and used in various locations. Representative examples of mobile electronic devices include mobile electronic phones, personal digital assistants, laptop computers, tablet computers, radios, cameras and camera accessories, watches, calculators, music players, global positioning system receivers, portable games, hard drives and other electronic storage devices, and the like.

Preferred mobile electronic devices are laptop computers and mobile electronic phones. Most preferred mobile electronic device is a mobile electronic phone.

The mobile electronic part according to the present invention may be selected from a large list of articles such as fitting parts, snap fit parts, screw bosses parts, mutually moveable parts, functional elements, operating elements, tracking elements, adjustment elements, carrier elements, frame elements, films, in particular speaker films, switches, connectors, cables, housings, any structural part integrated on housings and any other structural part other than housings as used in a mobile electronic devices, such as for example speaker parts.

By “mobile electronic device housing” is meant one or more of the back cover, front cover, antenna housing, frame and/or backbone of a mobile electronic device.

The housing may be a single article or comprise two or more components.

Non-limiting examples of structural parts integrated on housings mention can notably be made of ribs, screw bosses, snap-fits and the like, all integrally bonded to the inner surface of a housing.

By “backbone” is meant a structural component onto which other components of the device, such as electronics, microprocessors, screens, keyboards and keypads, antennas, battery sockets, and the like are mounted. The backbone may be an interior component that is not visible or only partially visible from the exterior of the mobile electronic device. The housing may provide protection for internal components of the device from impact and contamination and/or damage from environmental agents (such as liquids, dust, and the like). Housing components such as covers may also provide substantial or primary structural support for and protection against impact of certain components having exposure to the exterior of the device such as screens and/or antennas.

The mobile electronic device housing is preferably selected from the group consisting of a mobile phone housing, a tablet housing, a laptop computer housing and a tablet computer housing.

Another objective of the present invention is to provide a method for the manufacture of the above described mobile electronic parts comprising the following steps:

Step 1—coating at least part of the surface of a shaped metal part, as described above, with at least one polymer layer (L), wherein the metal is selected from a group consisting of magnesium, aluminum and alloys of these metals, and wherein said polymer layer (L) comprises at least one polymer selected from a (PAI) polymer, as described above or a (PESU) polymer, as described above, and
Step 2—forming a thermoplastic resin composition layer [layer (T)], as described above, onto the at least one polymer layer (L) of said shaped metal part.

Yet another objective of the present invention is to provide a method for the manufacture of the above described mobile electronic parts comprising only Step 1—being the coating of at least part of the surface of a shaped metal part with at least one polymer layer (L), wherein the metal is selected from a group consisting of magnesium, aluminum and alloys of these metals, and wherein said polymer layer (L) comprises at least one (PESU) polymer, as described above.

In Step 1 of the method of the present invention, the shaped metal part being coated by at least one polymer layer (L), as mentioned above, comprising the (PAI) polymer, as described above or (PESU) polymer, as described above, can be obtained by coating a shaped metal part by using known coating methods suitable for (PAI) polymers or (PESU) polymers.

A detailed description of coating processes in which (PAI) polymers are used, is available notably in PCT patent application WO 00/53677, U.S. Pat. No. 4,014,834, U.S. patent application No. 2005/0103224, the whole content of those are herein incorporated by reference. Typically, these coatings may be solventborne, waterborne or semi-aqueous.

As to this aim, the (PAI) polymers are suitably applied from a coating composition comprising a liquid medium [composition (PAI), herein after]. In general, said composition (PAI) can be a solvent-based, aqueous-based and a semi-aqueous based composition.

A typical example of an aqueous-based composition (PAI), in particular comprising the commercially available Torlon® AI-30 and Torlon® AI-50 polymers from Solvay Specialty Polymers USA, LLC, is notably described in PCT patent application WO 00/53677 wherein the PAI polymer in solid form, substantially solvent-free, is mixed with water in the presence of an amine, in particular a tertiary amine.

A typical example of semi-aqueous based composition (PAI), in particular comprising the commercially available Torlon® AI-10 polymer from Solvay Specialty Polymers USA, LLC, notably described in U.S. Pat. No. 4,014,834 wherein the PAI polymer in solid form, substantially solvent-free, is mixed with water in the presence of an amine, in particular a tertiary amine and additionally contain viscosity reducing agents such as notably furfuryl alcohol and a coalescing agent such as notably N-methylpyrrolidinone (NMP).

A typical example of solvent-based composition (PAI), in particular comprising the commercially available Torlon® 4000T and Torlon® 4000TF, from Solvay Specialty Polymers USA, LLC, wherein the PAI polymer in solid form, is dissolved in dipolar aprotic solvents such as notably NMP, DMAC, DMF, and DMSO to at most 35% solids at a temperature ranging from 80 until 120° C.

The composition (PAI) of the invention comprises advantageously at least 0.5% wt, preferably at least 1% wt, more preferably at least 3% wt of the (PAI) polymer with respect to the total weight of the composition.

The composition (PAI) of the invention comprises advantageously at most 75% wt, preferably at most 60% wt, more preferably at most 55% wt of (PAI) polymer with respect to the total weight of the composition.

As said, coating processes in which (PESU) polymers are used are known in the art.

In general in coating applications, the (PESU) polymers are suitably applied from a coating composition comprising a liquid medium [composition (PESU), herein after].

As to this aim, the (PESU) polymer, for example the commercially available Veradel® polyethersulfone (PESU) from Solvay Specialty Polymers USA, LLC, can be notably provided in dry solid form (as dry particles) or as dispersion in water or as latex.

In one specific embodiment of Step 1 of the method of the present invention, the composition (PESU) is obtained by dissolving the (PESU) polymer in dipolar aprotic solvents such as notably NMP, DMAC, DMF, and DMSO to at most 35% solids.

In another specific embodiment of Step 1 of the method of the present invention, the composition (PESU) is obtained by dispersion of the (PESU) polymer.

By “dispersion” is meant that the (PESU) polymer particles are stably dispersed in the aqueous medium, so that settling of the particles does not occur within the time when the dispersion will be used. Such dispersions can be obtained directly by the process known as dispersion polymerization (i.e. latex), optionally followed by concentration and/or further addition of surfactant. For those polymers that are soluble in organic solvents the dispersion can also be advantageously obtained by mixing the polymer solution with water, optionally containing surfactants, to precipitate polymer particles.

Otherwise, dispersions can be prepared by any means known to those skilled in the art. The dispersions are usually prepared by means of size-reduction equipment, such as, for example, a high-pressure homogenizer, a colloid mill, a fast pump, a vibratory agitator or an ultrasound device. The dispersions are preferably prepared by means of a high-pressure homogenizer or colloid mill and in a particularly preferred way by means of a high-pressure homogenizer.

The composition (PESU) of the invention comprises advantageously at least 0.5% wt, preferably at least 1% wt, more preferably at least 3% wt of (PESU) polymer with respect to the total weight of the composition.

The composition (PESU) of the invention comprises advantageously at most 75% wt, preferably at most 60% wt, more preferably at most 55% wt of (PESU) polymer with respect to the total weight of the composition.

The composition (PAI), as described above, or the composition (PESU), as described above, may further optionally comprise other ingredients such as heat-stable organic and inorganic pigments, fillers, certain epoxy and fluoropolymer copolymers, certain crosslinkers as notably described in U.S. 2005/0103224.

When one or more other ingredients are present, their total weight, based on the total weight of composition (PAI) or composition (PESU), is usually below 50%, preferably below 20%, more preferably below 10% and even more preferably below 5%.

As to standard known coating techniques, mention can notably be made of film coating, spray coating, curtain coating, casting, coil coating, roller coating, gravure coating, reverse roll coating, dip coating, spray coating, blade coating and the like. Techniques particularly adapted for coating the shaped metal part of the present invention, with the composition (PAI) or the composition (PESU) of the present invention are notably roller coating, dip coating, spray coating, blade coating.

It is further understood that after applying the composition (PAI) or the composition (PESU) of the present invention to the shaped metal part, according to the coating methods as described above, the layers of said composition (PAI) or the composition (PESU) can be further dried and baked or cured by the same methods as those described for known coating layers comprising a (PAI) polymer or a (PESU) polymer, and thus the polymer layer (L) is formed on the surface of the shaped metal part, resulting in a coated shaped metal part.

In other words, the drying and curing can be carried out according to ordinary practical skills.

Drying enables substantial removal of the liquid medium. Drying can be effected at any temperatures, from room temperature onward.

In general, the curing can realized by heat in a conventional oven, by light with near-infrared (NIR) energy or by chemical imidization.

Preferably, the curing is carried out by heat in a conventional oven in a temperature range from 245° C. to 450° C., more preferably from 300° C. to 400° C.

Usually, dry polymer layer (L) thicknesses from 1 μm to 20 μm are readily achieved in a single coating pass. Greater film polymer layer (L) can be achieved by applying multiple coatings, as described above.

If desired, the coated shaped metal part, as described above, can further be shaped by applying standard shaping technologies before carrying out Step 2.

For the purpose of the present invention, the shape of the metal part, as detailed above, can be formed by various machining processes, known in the art, into a configuration which is desired and fits best its encompassed end use in a mobile electronic device, and for use as an insert in injection molding process, as described in a preferred embodiment below.

For example, the shaped aluminum alloy part can be configured into the desired configuration from an aluminum alloy ingot, plate, bar or the like by machining processes including for example plastic working, sawing, milling, electrical discharge machining, drilling, press working, grinding, or polishing, which may be used singly or in combination.

The shaped part used in Step 1 has a surface which can be intended to be partially or totally coated with polymer layer (L) and, directly affixed to this latter, layer (T).

Embodiments wherein the surface of the shaped metal part is partially coated with polymer layer (L) are notably intended to provide accessible surface for subsequent steps or processing.

Embodiments wherein the surface of the shaped metal part is totally coated with polymer layer (L) are still within the scope of the invention.

If necessary, it can be required that the shaped metal part, before being coated by a polymer layer (L), need to be pretreated by known surface treatment processes including notably grit blasting, flame spraying, polishing, sandblasting, shot blasting, grinding, or barreling and the like. Said surface treatment processes are advantageously used for removing for example an oil or fat layer left on the surface of the shaped metal part after the machining processes, described above, a rust layer formed by oxidation or hydroxidation, peeling off an oxide layer, a corrosion product layer, and the like.

The above described surface treatment processes advantageously increase the surface roughness, thereby enhancing the bond effect between the surface of the shaped metal part and the polymer layer (L).

If desired, in addition to said surface treatment processes, cleaning processes, in particular washing, to remove grease and other contaminants which might interfere with adhesion, can be carried out. It is preferable to perform washing with an organic solvent and/or rinsing with water in combination, depending on the kind of contamination. If a water-soluble organic solvent, e.g. acetone, methanol, or ethanol, is used, it is easy to remove the organic solvent by rinsing with water after the shaped metal part has been dipped in the organic solvent to remove oily contamination. If oily matter is firmly attached to the surface, it may be washed with an organic solvent, e.g. benzene, or xylene.

Nevertheless, the composition (PAI) or the composition (PESU), as described above, can also notably be applied on smooth substrates, treated only by washing to remove grease and other contaminants which might interfere with adhesion, yielding good coating properties.

If desired, in addition to said surface treatment processes and/or cleaning processes, the surface of the shaped metal part can be further treated by carrying out the first four steps of the NMT-method, as mentioned above, including the steps of alkali etching, acid treatment (i.e. neutralization treatment), T-treatment (i.e. contact treatment) and rinsing and drying.

A detailed description of these four steps of the NMT-method is available notably in the Master Thesis, entitled “‘Nano Molding Technology on Cosmetic Aluminum Parts in Mobile Phones—an experimental study’, by Carl-Ola Annefors and Sara Petersson for Division of Production and Materials Engineering at Lund University, the whole content of which is herein incorporated by reference, and in European Patent Applications EP1459882 and EP1559542, the whole content of those are herein incorporated by reference, as mentioned above.

In Step 2 of the method of the present invention, the composition (T), as described in detail above, can advantageously be fixed to the at least one polymer layer (L) coated onto the shaped metal part, as described in detail above, by using conventional techniques, known on the art including but not limited to injection molding, heat pressing, extruding, casting, compression molding, sintering, machining, or combinations thereof.

Injection molding, heat pressing, extruding and combinations thereof are preferred. Injection molding is especially preferred.

The injection molding can typically be carried out according to standard methods known in the art, all experimental parameters can be applied according to ordinary practice in the art.

It is further understood that the injection molding process as described in detail in the section “Injection Molding” of the Master Thesis, by Carl-Ola Annefors and Sara Petersson, as mentioned above, can also be applied in Step 2 of the method of the present invention, it is understood that the skilled person will easily adapt the experimental parameters which fits best to the needs of the present invention.

In a preferred embodiment of Step 2 of the method of the present invention, the composition (T), as described in detail above, is molded over the at least one polymer layer (L) coated onto the shaped aluminum alloy part by using conventional overmolding techniques chosen from injection molding, heat pressing, extruding and combinations thereof, thereby forming a composition (T) overmold onto said polymer layer (L). The most preferred embodiment of the overmolding technique is injection molding.

The external surface of composition (T) overmold may have any feature, shape, size, etc., necessary to its function, regardless of the shape and size of underlying coated shaped metal part.

The Applicant has surprisingly found that overmolding onto a polymer layer (L) comprising the (PAI) polymer or (PESU) polymer is very advantageous because the (PAI) polymer or (PESU) polymer used as adhesives are providing i) excellent adhesion, with the composition (T) overmold ii) excellent thermal resistance to maintain good adhesion in high temperature molding operations, and iii) chemical resistance to annodization if that is required.

The composition (T), as described above, can be prepared by a variety of methods involving intimate admixing of the at least polymer (T), optionally the reinforcing fillers, as described above, and optionally the other ingredients, as detailed above, desired in the formulation, for example by melt mixing or a combination of dry blending and melt mixing. Typically, the dry blending of the at least one polymers (T), optionally the reinforcing filler and optionally the other ingredients, as above details, is carried out by using high intensity mixers, such as notably Henschel-type mixers and ribbon mixers.

So obtained powder mixture of said composition (T) can suitable be used in Step 2 of the method of the present invention, as described above, or the obtained powder mixture can be a concentrated mixture to be used as masterbatch and diluted in further amounts of the at least polymer (T), optionally the reinforcing fillers, as described above, and optionally the other ingredients, as detailed above, in Step 2 of the method of the present invention.

It is also possible to manufacture composition (T) of the invention by further melt compounding the powder mixture as above described. As said, melt compounding can be effected on the powder mixture as above detailed, or directly on the at least polymer (T), optionally the reinforcing fillers, as described above, and optionally the other ingredients, as detailed above. Conventional melt compounding devices, such as co-rotating and counter-rotating extruders, single screw extruders, co-kneaders, disc-pack processors and various other types of extrusion equipment can be used. Preferably, extruders, more preferably twin screw extruders can be used.

If desired, the design of the compounding screw, e.g. flight pitch and width, clearance, length as well as operating conditions will be advantageously chosen so that sufficient heat and mechanical energy is provided to advantageously fully melt the powder mixture or the ingredients as above detailed and advantageously obtain a homogeneous distribution of the different ingredients. Provided that optimum mixing is achieved between the bulk polymer and filler contents, it is advantageously possible to obtain strand extrudates which can be chopped by means e.g. of a rotating cutting knife after some cooling time on a conveyer with water spray. Thus, for example composition (T) which may be present in the form of pellets or beads can then be further used in Step 2 of the method of the present invention, as discussed above.

The mobile electronic parts according to the present invention may be further shaped into in a part having any type of size and shape by applying standard shaping technologies.

As mentioned above, anodization is an important process as a post treatment of metal parts and/or metal/plastic parts, as typically used for building an extra oxide layer on the metal part surface.

The Applicant has surprisingly found that the mobile electronic parts according to the present invention has excellent chemical resistance properties to various aggressive acids and thus has improved chemical resistance over prior art mobile electronic parts.

In a specific embodiment of the present invention, the mobile electronic parts according to the present invention may further undergo an anodizing treatment.

Said anodizing treatment can be carried out according to various conventional methods. In general, an anodizing treatment is carried out in four steps including a pre-treatment, an anodizing, a coloring and a sealing, where the pre-treatment is divided into three process steps: degreasing, etching and desmutting. After each step, rinsing the parts in water is recommended. For example, the anodizing step is carried out in an acid medium such as a sulfuric acid solution or a sulfuric acid containing sulfophthalic acid solution according to well known procedures.

Another aspect of the present invention is an anodized mobile electronic part obtained after an anodizing treatment of the mobile electronic part, as described above.

Another objective of the present invention is to provide a method for the manufacture of a mobile electronic device comprising the mobile electronic part, as described in detail above, said method including the steps of:
providing as components at least a circuit board, a screen and a battery;
providing at least one mobile electronic part, as described above;
assembling at least one of said components with said part or mounting at least one of said components on said part.

Should the disclosure of any patents, patent applications, and publications which are incorporated herein by reference conflict with the description of the present application to the extent that it may render a term unclear, the present description shall take precedence.

### EXAMPLES

The invention will now be described in more details with reference to the following examples, whose purpose is merely illustrative and not intended to limit the scope of the invention.

### Raw Materials

Aluminum alloy plate A5052/H38 as purchased from Alcoa Inc. TORLON® AI-30 commercially available from Solvay Specialty Polymers USA, LLC.
Diethylaminoethanol as purchased from Arkema Inc.
Avaspire® AV-651 unreinforced polyaryletherketone (PAEK) commercially available from Solvay Specialty Polymers USA, LLC.

### Example 1

A metal substrate, e.g. commercially available aluminum alloy plate A5052/H38 with a thickness of 1 mm, is stamped into a part used in mobile electronics, e.g. cover, frame, backing Said aluminum alloy part is dipped in 1 liter of ethanol for 10 minutes under application of ultrasonic waves, and then is dipped in 4 liters of tap water under stirring. Thereafter, the aluminum alloy part is put into a plastic basket and washed with running tap water. Next, the aluminum alloy part is dipped in a 2% aqueous caustic soda solution for 2 minutes, followed by rinsing with ion-exchange water. Then, the aluminum alloy part is dipped in a 1% aqueous hydrochloric acid solution for 1 minute to effect neutralization. Then, the aluminum alloy part is dip-washed in 4 liters of ion-exchange water, followed by rinsing with running ion-exchange water.

One liter of a 2% aqueous ammonia solution is prepared. A 1% aqueous caustic soda solution prepared separately is dropped into the aqueous ammonia solution under stirring to adjust the pH to 11.0 at 50° C. The treated aluminum alloy part, as stated above, is dipped in this prepared aqueous solution for 2 minutes and then thoroughly washed with ion-exchange water. The aluminum alloy part is dried with hot air at 60° C. for 20 minutes.

A polyamide-imide (PAI) solution (i.e. 7% polymer solids solution) is prepared whereby 233.33 grams of polyamide amic acid (TORLON® AI-30 from Solvay Advanced Polymers) and 926.97 grams of water are mixed and heated until 65° C. to make a slurry. 39.69 grams of diethylaminoethanol is added to this slurry via a syringe, and after about 6 hours, the polymer is completely dissolved. A (PAI) solution is obtained.

A thin layer of this (PAI) solution is then sprayed onto the aluminum alloy part, using a spray gun, and is then cured by heating in a conventional oven at 235° C. for 15 min to provide the PAI coated aluminum alloy part.

In order to produce the mobile electronic part, the PAI coated aluminum alloy part is heated to a temperature between 100 and 200° C. and inserted into an insert mold of an injection molding machine, which had been heated to between 150 and 200° C., and the Avaspire® AV-651 unreinforced (PAEK) resin is injected into the mold at a melt temperature in the range of 370-410° C. After 40 seconds, the mold is opened.

### Example 2

A metal substrate, e.g. commercially available aluminum alloy plate A5052/H38 with a thickness of 1 mm, is stamped into a part used in mobile electronics, e.g. cover, frame, backing Said aluminum alloy part is then blasted with sand to remove contaminants and roughen the surface, and then cleaned with a volatile organic solvent.

A polyamide-imide (PAI) composition is prepared whereby 233.33 grams of polyamide amic acid (TORLON® AI-30 from Solvay Advanced Polymers) and 926.97 grams of water are mixed and heated until 65° C. to make a slurry. 39.69 grams of diethylaminoethanol is added to this slurry via a syringe, and after about 6 hours, the polymer is completely dissolved. A (PAI) solution is obtained. A thin layer of this (PAI) solution is then sprayed onto the aluminum alloy part, using a spray gun, and is then cured by heating in a conventional oven at 235° C. for 15 min to provide the PAI coated aluminum alloy part.

In order to produce the mobile electronic part, the PAI coated aluminum alloy part is heated to a temperature between 100 and 200° C. and inserted into an insert mold of an injection molding machine, which had been heated to between 150 and 200° C., and the Avaspire® AV-651 unreinforced (PAEK) resin is injected into the mold at a melt temperature in the range of 370-410° C. After 40 seconds, the mold is opened.

### Example 3

An aluminum alloy sheet or coil is coated on one or both sides with a (PAI) solution, which is prepared according to the procedure as mentioned in example 2, by using a roll coater and is then cured by NIR energy to provide the PAI coated aluminum alloy sheet or coil.

In order to produce the mobile electronic part, the PAI coated aluminum alloy part is heated to a temperature between 100 and 200° C. and inserted into an insert mold of an injection molding machine, which had been heated to between 150 and 200° C., and the Avaspire® AV-651 unreinforced (PAEK) resin is injected into the mold at a melt temperature in the range of 370-410° C. After 40 seconds, the mold is opened.

1-15. (canceled)

16. A mobile electronic part comprising:
(i) a shaped metal part, at least part of the surface thereof being coated with at least one polymer layer (L), wherein the metal is selected from the group consisting of magnesium, aluminium, and alloys of these metals, and wherein said polymer layer (L) comprises at least one polymer selected from an aromatic polyamide-imide polymer, (PAI) polymer, or a poly(ethersulfone) polymer, (PESU) polymer, and
(ii) a thermoplastic resin composition layer, layer (T), fixed to the at least one polymer layer (L) of said shaped metal part, wherein said layer (T) comprises at least one thermoplastic polymer, polymer (T).

17. A mobile electronic part comprising a shaped metal part, at least part of the surface thereof being coated with at least one polymer layer (L), wherein the metal is selected from the group consisting of magnesium, aluminium, and alloys of these metals, and wherein said polymer layer (L) comprises at least one poly(ethersulfone) polymer, (PESU) polymer.

18. The mobile electronic part according to claim 16, wherein the polymer (T) is selected from the group consisting of polyamides, polyesters, pol(yaryletherketone)s, poly(arylethersulfone)s, polyimides, polyetherimides, polyamideimide, liquid crystalline polymers, polycarbonates, polyolefins, poly(phenylene sulfide), polyphenylene oxide, polyacrylates, acrylonitrile butadiene styrene polymer, polyoxymethylene, polystyrene, polyphenylene sulfide, polyvinylidene fluoride, polytetrafluoroethylene, polyvinylidene chloride, polyvinyl chloride, and thermoplastic elastomers.

19. The mobile electronic part according to claim 16, wherein the polymer (T) is selected from the group consisting of at least one poly(arylethersulfone) polymer, (PAES) polymer, at least one poly(aryletherketone) polymer, (PAEK) polymer, and mixtures thereof.

20. The mobile electronic part according to claim 16, wherein the (PAI) polymer comprises more than 50% moles of recurring units comprising at least one aromatic ring, at least one imide group, as such and/or in its amic acid form, and at least one amide group which is not included in the amic acid form of an imide group, recurring units (R_{PAI}), said recurring units (R_{PAI}) being selected from the group consisting of: 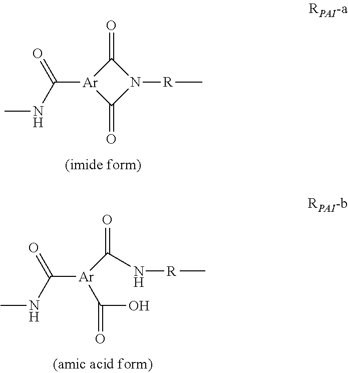
wherein:
Ar is a trivalent aromatic group;
R is a divalent aromatic group;
and said (PAI) polymer is provided as a coating composition comprising a liquid medium, composition (PAI).

21. The mobile electronic part according to claim 16, wherein the (PESU) polymer comprises more than 50% by moles of recurring units of formula (jjj): 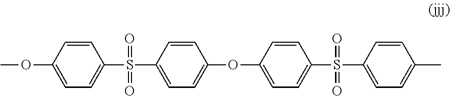
and said (PESU) polymer is provided as a coating composition comprising a liquid medium, composition (PESU).

22. The mobile electronic part according to claim 16, wherein said mobile electronic part is selected from a group consisting of fitting parts, snap fit parts, screw bosses parts, mutually moveable parts, functional elements, operating elements, tracking elements, adjustment elements, carrier elements, frame elements, films, speaker films, switches, connectors, cables, housings, any structural part integrated on housings, and any other structural part in a mobile electronic device other than housings.

23. The mobile electronic part according to claim 16, wherein said mobile electronic part has been anodized.

24. A method for manufacturing the mobile electronic part according to claim 16 comprising:
coating at least part of the surface of the shaped metal part with the at least one polymer layer (L), wherein the metal is selected from a group consisting of magnesium, aluminium, and alloys of these metals, and wherein said polymer layer (L) comprises at least one polymer selected from an aromatic polyamide-imide polymer, (PAI) polymer, or a poly(ethersulfone) polymer, (PESU) polymer, and
forming the thermoplastic resin composition layer, the layer (T), wherein said layer (T) comprises the at least one thermoplastic polymer, polymer (T), onto the at least one polymer layer (L) of said shaped metal part.

25. The method according to claim 24, wherein the layer (T) is formed by injection molding, heat pressing, extruding, casting, compression molding, sintering, machining, or combinations thereof.

26. The method according to claim 24, wherein the formation of the polymer layer (L) on at least part of the surface of the shaped metal part includes applying a coating composition comprising the (PAI) polymer and a liquid medium, composition (PAI) onto at least part of the surface of the shaped metal part by a coating techniques, followed by drying and baking.

27. A method for manufacturing the mobile electronic part according to claim 17 comprising coating at least part of the surface of the shaped metal part with at least one polymer layer (L), wherein the metal is selected from the group consisting of magnesium, aluminium, and alloys of these metals, and wherein said polymer layer (L) comprises at least one poly(ethersulfone) polymer, (PESU) polymer.

28. The method according to claim 24, wherein the formation of the polymer layer (L) on at least part of the surface of the shaped metal part includes applying a coating composition comprising the (PESU) polymer and a liquid medium, composition (PESU), onto at least part of the surface of the shaped metal part by coating techniques followed by drying and baking.

29. The method according to claim 27, wherein the formation of the polymer layer (L) on at least part of the surface of the shaped metal part includes applying a coating composition comprising the (PESU) polymer and a liquid medium, composition (PESU), onto at least part of the surface of the shaped metal part by coating techniques followed by drying and baking.

30. A mobile electronic device comprising the mobile electronic part according to claim 16.

31. A method for manufacturing the mobile electronic device according to claim 30, the method comprising:
providing at least one component selected from at least a circuit board, a screen, and a battery;
providing at least one mobile electronic part, according to claim 1; and
assembling the at least one component with the at least one mobile electronic part, or mounting the at least one component on the at last one mobile electronic part.

32. The mobile electronic part according to claim 20, wherein Ar is selected from the group consisting of: 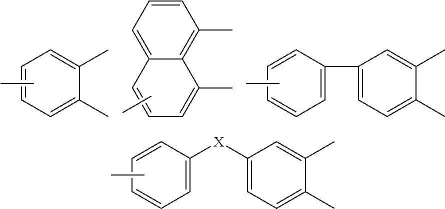
and corresponding optionally substituted structures; X being —O—, —C(O)—, —CH₂—, —C(CF₃)₂—, —(CF₂)_{q}—; and q is an integer from 1 to 5.

33. The mobile electronic part according to claim 20, wherein R is selected from the group consisting of: 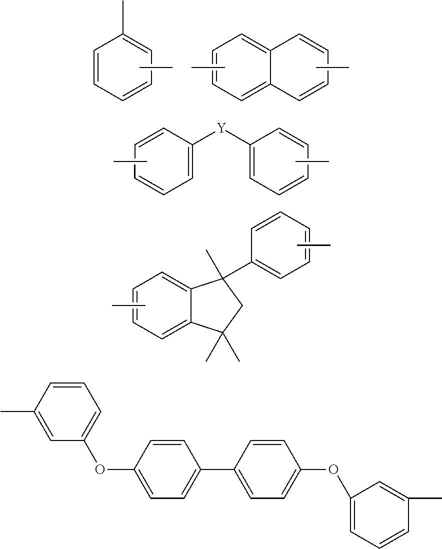
and corresponding optionally substituted structures; Y being —O—, —S—, —SO₂—, —CH₂—, —C(O)—, —C(CF₃)₂—, —(CF₂)_{q}; and q is an integer from 1 to 5.

34. The method according to claim 26, wherein the coating technique is selected from film coating, spray coating, curtain coating, casting, coil coating, roller coating, gravure coating, reverse roll coating, dip coating, spray coating, blade coating, and similar techniques.

35. The method according to claim 28, wherein the coating technique is selected from film coating, spray coating, curtain coating, casting, coil coating, roller coating, gravure coating, reverse roll coating, dip coating, spray coating, blade coating, and similar techniques.

36. The method according to claim 29, wherein the coating technique is selected from film coating, spray coating, curtain coating, casting, coil coating, roller coating, gravure coating, reverse roll coating, dip coating, spray coating, blade coating, and similar techniques.
